(19) United States
(12) Patent Application Publication
(10) Pub. No.: US 2010/0181191 A1
(43) Pub. Date: Jul. 22, 2010

(54) SPUTTERING APPARATUS

(75) Inventor: Hiroshi Tamagaki, Hyogo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Kobe Seiko Sho( Kobe Steel, Ltd.), Kobe-shi (JP)

(21) Appl. No.: 12/668,914

(22) PCT Filed: May 29, 2008
(86) PCT No.: PCT/JP08/59880

§ 371 Date: Jan. 13, 2010

(30) Foreign Application Priority Data
Jul. 20, 2007 (JP) 2007-189471

(51) Int. Cl. C23C 14/35

(52) U.S. Cl. 204/298.08; 204/298.21

(57) ABSTRACT

It is an object of the present invention to provide a sputtering apparatus capable of suppressing local consumption of axial end portions of a rotatable cylindrical target to make uniform an erosion area in the cylindrical target and thereby improving the service life of the cylindrical target. The apparatus includes a pair of sputter evaporation sources 2 each having a rotatable cylindrical target 13 and a magnetic field generating member 14 disposed inside the cylindrical target 13; and a sputter power source 3 for the supply of discharge electric power to the cylindrical targets 13, using the cylindrical targets 13 as cathodes. Both the cylindrical targets 13 are disposed in such a manner that the respective center axes are parallel to each other, and the magnetic field generating members 14 generate a magnetic field having magnetic lines of force acting in directions attracting through surfaces of the cylindrical targets 13.

### FIELD OF ART

The present invention relates to a sputtering apparatus provided with a rotatable cylindrical target and aims at improving the service life of the cylindrical target.

### BACKGROUND ART

Sputtering is a kind of a physical vapor deposition method. This method includes supplying a discharge electric power to a target which is made a cathode electrically within sputtering gas (discharge gas) introduced into a vacuum chamber, ionizing the sputtering gas in a plasma atmosphere and making the resulting ions impinge on the surface of the target, and allowing deposition particles to be released from the target upon the impingement and be deposited on a substrate to form a film on the substrate surface.

Recently, such a sputtering apparatus as shown in FIG. 10, which is provided with a so-called rotary magnetron sputter evaporation source 31, has been proposed as a sputtering apparatus with high deposition rate and good utilization of a target which constitutes a sputter evaporation source (Patent Document 1). The rotary magnetron sputter evaporation source 31 is provided with a cylindrical member 32, a cylindrical target 33, and a magnetic field generating member 34.

The cylindrical member 32 is provided rotatably around its center axis and the cylindrical target 33 is attached to an outer periphery portion of the cylindrical member 32. The magnetic field generating member 34 is provided inside the cylindrical member 32 and has a center magnet 36 and an outer magnet 37 different in polarity from each other and further has a magnetic connector member 38 for connecting those magnets magnetically. The center magnet 36 is rectilinear, extending along the center axis of the cylindrical member 32 (and the cylindrical target 33) and the outer magnet 37 is disposed so as to surround the center magnet 36.

The magnetic field generating member 34 generates a so-called race-track magnetic field which forms magnetic lines of force connecting the center magnet 36 and the outer magnet 37 with each other through the cylindrical target 33 and which comprises two straight-line portions parallel to a center axis of the cylindrical target 33 and arc portions connecting both ends of the two straight-line portions.

According to the rotary magnetron sputter evaporation source 31, electrons generated by discharge are confined in the race-track magnetic field and plasma Pr of a race-track shape is formed in the longitudinal direction of the cylindrical target 33, as shown in FIG. 11. As a result, an erosion area of a race-track shape is formed on the surface of the cylindrical target 33 and deposition particles are released efficiently from the erosion area. Further, the cylindrical target 33, together with the cylindrical member 32, rotates relatively with respect to the race-track discharge plasma Pr, thereby spreading the erosion area to the whole surface of an outer periphery of the cylindrical target 33 and thus improving the utilization of the target.

However, as shown in FIG. 12, in the rotary magnetron sputter evaporation source 31 which forms the race-track magnetic field as noted above there is the problem that local consumed portions 41 which are consumed heavily are formed at end portions of the erosion area in the cylindrical target 33. The reason is that when the cylindrical target 33 rotates, the race-track discharge plasma Pr that is present at 180° lapping arc end portions become longer in plasma projection and that therefore erosion is promoted in comparison with that in the straight-line portion. Thus, there is the problem that the life of the cylindrical target 33 depends on local consumption at end portions thereof and that despite the central portion of the cylindrical target 33 being still thick enough for use, it cannot be utilized effectively.

Although the service life of the cylindrical target can be prolonged by increasing the thickness of each end portion of the cylindrical target at the time of fabricating the same target, it is difficult to fabricate and implement the cylindrical target of such a special shape.

### [Patent Document 1] Japanese Patent Publication No. 1991-68113

### DISCLOSURE OF THE INVENTION

In view of the above-mentioned circumstances it is an object of the present invention to provide a sputtering apparatus capable of suppressing local consumption of axial end portions of a rotatable cylindrical target to make uniform an erosion area in the cylindrical target and thereby improving the service life of the cylindrical target.

As means for achieving the above-mentioned object a first sputtering apparatus according to the present invention comprises a pair of sputter evaporation sources and a sputter power source. Each of the sputter evaporation sources has a cylindrical target, the cylindrical target having a center axis and being disposed rotatably about the center axis, and a magnetic field generating member disposed in a direction parallel to the center axis of the cylindrical target. The cylindrical targets in the sputter evaporation sources are disposed in such a manner that the respective center axes are parallel to each other. With the cylindrical targets as cathodes, the sputter power source supplies discharge electric power to the cylindrical targets. The magnetic field generating members in both sputter evaporation sources generate a magnetic field having magnetic lines of force which act in directions attracting through the surfaces of the cylindrical targets in the sputter evaporation sources.

The magnetic field thus formed between the cylindrical targets which constitute cathodes traps electrons generated by ionization of sputtering gas during deposition, causing Penning discharge to take place in the area of the magnetic field. The Penning discharge occurs strongly in the magnetic field-existing area, while at an outer periphery portion thereof there occurs plasma drift caused by an electric field, so that substantially uniform discharge plasma occurs in the discharge-existing area. Thus, unlike magnetron discharge which occurs in conventional sputtering apparatus, there exist no arcuate plasma portions connecting end portions of two linear plasmas, so that at the time of deposition by rotation of the cylindrical targets, deposition particles can evaporate quickly and uniformly from the outer periphery surfaces of the cylindrical targets corresponding to the plasma area. This prevents local consumption of the cylindrical targets and thereby improves the utilization rate and hence the service life of the cylindrical targets.

A second sputtering apparatus according to the present invention comprises a sputter evaporation source, a sputter power source, and an auxiliary electrode structure. The sputter evaporation source has a cylindrical target, the cylindrical target having a center axis and being disposed rotatably around the center axis, and a magnetic field generating member disposed in a direction parallel to the center axis of the cylindrical target, wherein the sputter power source supplies discharge electric power to the cylindrical target with the cylindrical target as a cathode. The auxiliary electrode structure has an auxiliary electrode member disposed opposingly in parallel or approximately in parallel with the cylindrical target in the sputter evaporation source and an auxiliary magnetic field generating member attached to the auxiliary electrode member, wherein the auxiliary magnetic field generating member and the magnetic field generating member provided in the sputter evaporation source generate a magnetic field, the magnetic field having magnetic lines of force acting in directions attracting through the surface of the cylindrical target.

Since this second sputtering apparatus has the auxiliary electrode structure, it is possible to expect the same effect as in the first sputtering apparatus also in case of using a single sputter evaporation source. The auxiliary electrode member may be connected as a cathode to a sputter electrode together with the cylindrical target in the sputter evaporation source, or may be floating electrically.

### BRIEF DESCRIPTION OF THE DRAWINGS

FIG. 1 is a partial vertical sectional view of a sputtering apparatus according to a first embodiment of the present invention.

FIG. 2 is a front view of a cylindrical target in the sputtering apparatus, showing a discharge area used in deposition in the same apparatus.

FIG. 3 is a sectional view of the cylindrical target in the sputtering apparatus, showing a state of consumption of the cylindrical target.

FIG. 4 is a partial vertical sectional view of a sputtering apparatus according to a second embodiment of the present invention.

FIG. 5 is a partial vertical sectional view of a sputtering apparatus according to a third embodiment of the present invention.

FIG. 6 is a vertical sectional view of a sputtering apparatus according to a fourth embodiment of the present invention.

FIG. 7 is a vertical sectional view showing a principal portion of a sputtering apparatus according to a fifth embodiment of the present invention.

FIG. 8 is a vertical sectional view showing a principal portion of a sputtering apparatus according to a sixth embodiment of the present invention.

FIG. 9 is a partially sectional plan view showing a principal portion of a sputtering apparatus according to a seventh embodiment of the present invention.

FIG. 10 is a cross-sectional view of a rotary magnetron sputter evaporation source used in a conventional sputtering apparatus.

FIG. 11 is a front view of a cylindrical target in the conventional sputtering apparatus, showing a discharge area used in deposition in the same apparatus.

FIG. 12 is a sectional view of the cylindrical target in the conventional sputtering apparatus, showing a state of consumption of the target in the same apparatus.

### BEST MODE FOR CARRYING OUT THE INVENTION

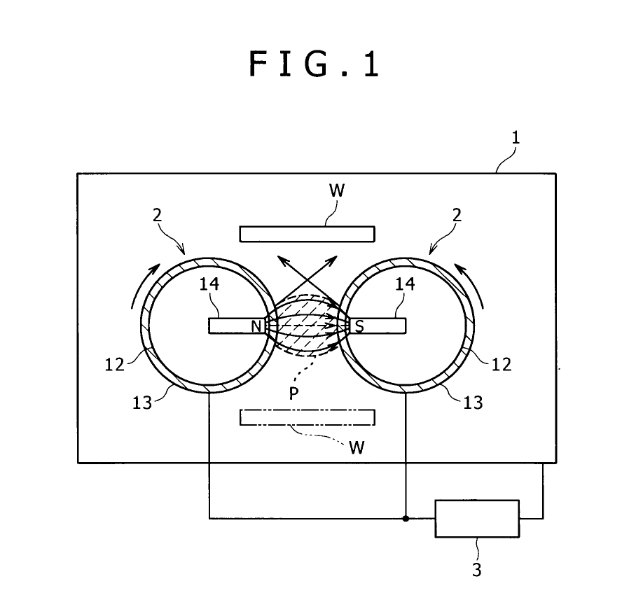

A sputtering apparatus according to a first embodiment of the present invention will be described below with reference to FIGS. 1 to 3.

As shown in FIG. 1, this sputtering apparatus is provided with a vacuum chamber 1 formed of a conductive material, a pair of sputter evaporation sources 2, 2 disposed side by side within the vacuum chamber 1, and a sputter power source 3 for the supply of discharge electric power to the sputter evaporation sources 2, 2.

In this embodiment a DC power source is used as the sputter power source 3 and a negative electrode thereof is connected to cylindrical targets 13 to be described later which targets are included in the sputter evaporation sources 2, 2, respectively, while a positive electrode thereof is connected to the vacuum chamber 1. To the vacuum chamber 1 are connected both a decompressor for maintaining the interior of the vacuum chamber 1 at a predetermined gas pressure and a sputtering gas (discharge gas) supply device. These components are not shown because the constructions thereof are well known.

The pair of sputter evaporation sources 2, 2 is each provided with a cylindrical member 12, a cylindrical target 13, and a magnetic field generating member 14.

The cylindrical member 12 has a center axis and is disposed within the vacuum chamber 1 so as to be rotatable around the center axis. The cylindrical target 13 is attached to an outer periphery portion of the cylindrical member 12 so as to be concentric with the cylindrical member 12. The center axis of the cylindrical member 12 and the cylindrical target 13 in one sputter evaporation source 2 and the center axis of the cylindrical member 12 and the cylindrical target 13 in the other sputter evaporation source 2 confront each other in a parallel or approximately parallel attitude.

In the vacuum chamber 1, a substrate W to be deposited is disposed. The substrate W is disposed so as to confront a space portion between the cylindrical targets 13 and 13 at a position spaced away, in a direction orthogonal to the disposed direction of both cylindrical targets 13, from the space portion. More specifically, a substrate holder (not shown) is installed within the vacuum chamber 1 and the substrate W is held removably by the substrate holder.

In this embodiment each magnetic field generating member 14 is constituted by a rod-like magnet of a square cross section and is disposed inside the cylindrical member 12 in the associated sputter evaporation source 2 in such a manner that the magnetic field generating member 14 extends along the center axis of the cylindrical member 12 and the cylindrical target 13. Preferably, the length of each magnetic field generating member 14 is set a little shorter than the length of the cylindrical target 13 so that both ends in the longitudinal direction (the direction parallel to the axial direction of the target 13) of the magnetic field generating member 14 are positioned slightly inside both ends of the cylindrical target 13.

Each magnetic field generating member 14 is disposed in such a manner that magnetic poles thereof are positioned at both radial ends of the associated cylindrical member 12 and that one (hereinafter referred to as “inner surface-side magnetic pole”) of the magnetic poles is positioned near an outer periphery surface of the cylindrical member 12, that is, near an inner periphery surface of the associated cylindrical target 13. The inner surface-side magnetic pole of the magnetic field generating member 14 in one sputter evaporation source 2 and the inner surface-side magnetic pole of the magnetic field generating member 14 in the other sputter evaporation source 2 have polarities opposite to each other. Therefore, in the space between the magnetic field generating members 14 and 14, there is formed a magnetic field in which magnetic lines of force attract through the cylindrical targets 13, 13.

In this embodiment, moreover, the magnetic field generating members 14 are disposed in such a manner that when a straight line connecting the magnetic poles of the magnetic field generating members 14 is designated as a magnetic pole center line and a straight line connecting the center axes of the cylindrical targets 13 is designated as a reference line, in cross sections of the cylindrical members 12 (cylindrical targets 13), the magnetic pole center line of the magnetic field generating members 14 and the reference line are aligned with each other. As shown in FIG. 1, the thus-disposed magnetic field generating members 14 form a magnetic field having an array of magnetic lines symmetric with respect to the reference line.

As a magnet constituting the magnetic field generating member 14, a magnet having large residual flux density such as a samarium-cobalt magnet and a neodymium magnet is preferable. However, it is possible to use other kinds of magnets such as a ferrite magnet and a superconductive magnet, and an electromagnet. A plurality of magnetic sources may be combined, for example a permanent magnet and the electromagnet may be combined.

The following description is now provided about a method of depositing by the sputtering apparatus described above.

First, the interior of the vacuum chamber 1 is evacuated and sputtering gas, e.g., Ar, is introduced at a pressure of about 0.1˜10 Pa into the space between the cylindrical targets 13. Then, with the two juxtaposed cylindrical targets 13, 13 as cathodes, a negative voltage is applied to those targets from the sputter power source 3.

The said voltage causes discharge between the cylindrical targets 13 and 13 and this discharge ionizes the sputtering gas, causing electrons to be produced. These electrons are confined in between the electrodes concerned, i.e., the targets 13 and 13, due to trapped by the magnetic field formed in the space portion between the cylindrical targets 13 and 13 and due to the presence of the cylindrical targets 13, 13 which function as negative electrodes, causing the so-called Penning discharge.

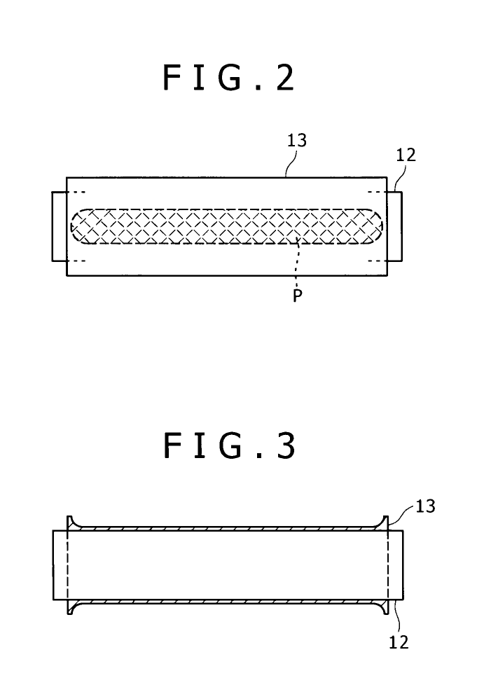

As shown in FIG. 1, the Penning discharge occurs strongly in the area where the magnetic field exists and plasma drift is induced by the electric field at the outer periphery portion thereof, so that a substantially uniform discharge is generated in the area where the magnetic field exists. Consequently, as shown in FIG. 2, an oval discharge plasma P is formed in the area where the Penning discharge is occurring, sputtering the surface of the cylindrical targets 13 facing the plasma P. Deposition particles released from the target surfaces by the sputtering are deposited on a substrate W disposed to face the space portion between the cylindrical targets 13 and 13.

In the deposition, the outer periphery surface of the cylindrical targets 13 which surface confront the discharge plasma P confined in the discharge area in the Penning discharge are consumed. However, when deposition is performed under rotation of the cylindrical targets 13, 13 together with the cylindrical members 12 while maintaining the positional relation between the magnetic field generating members 14 and 14, that is, while maintaining the state of the magnetic field formed between the cylindrical targets 13 and 13, the outer periphery surface of each cylindrical target 13 is consumed almost uniformly through the overall length of the discharge area, as shown in FIG. 3.

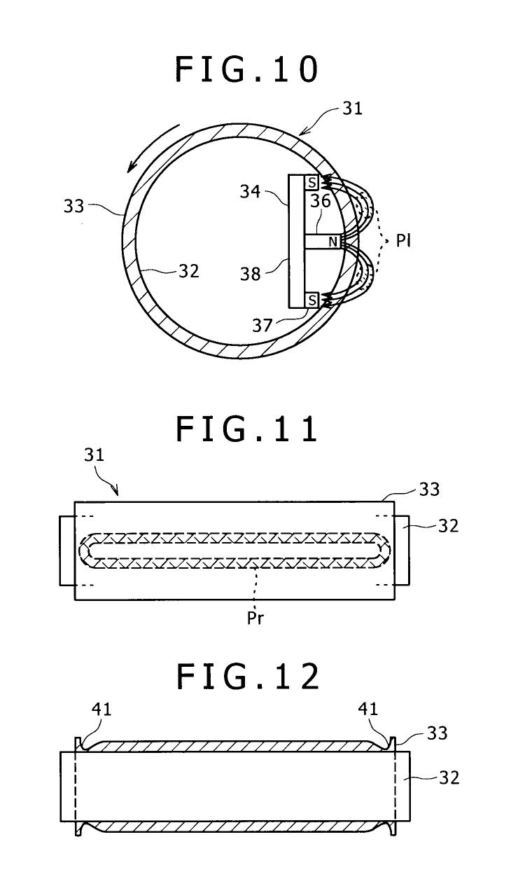

In this sputtering apparatus there is not formed plasma of a race-track shape caused by magnetron discharge as in the conventional sputtering apparatus shown in FIGS. 10 to 12. That is, since there are no arcuate plasma portions connecting end portions of two straight-line plasmas formed in the direction of the center axis of the cylindrical target 13, there are no locally long portions of plasma radiation during rotation of the cylindrical target 13. This prevents local consumption at end portions of the cylindrical target 13.

Thus, according to the sputtering apparatus of this embodiment it is possible to improve the utilization and service life of the target material.

In addition, the sputtering apparatus described above has the following advantages in point of deposition. The substrate W is installed at a position deviated from the discharge area between the cylindrical targets 13 and 13, and consequently there is no fear of strong radiation of plasma to the film during the deposition. Therefore, the sputtering apparatus is suitable for applications which ion bombardment or the like should be prevented from damaging. Moreover, since the substrate W is not directly opposed to the surfaces of the sputtering cylindrical surfaces 13, strong radiations of ions reflected by the targets' surfaces or negative ions produced from the targets' surfaces to the substrate W is suppressed. Consequently, improvement of film properties can be expected for example in depositing a transparent conductive film such as ITO in which a bad influence of high energy ions generated at the targets poses a problem.

Further, in the conventional rotary magnetron sputter evaporation source the surface of a target undergoes a significant change in the intensity of a magnetic field with consumption of the target, whereas in the sputtering apparatus of the above embodiment the change in the intensity of a magnetic field with consumption of each target is less conspicuous than in the case of the magnetron magnetic field, thus permitting the use of a target larger in wall thickness, i.e., a target of a longer life.

As the sputtering gas, not only the exemplified Ar gas but also a suitable inert gas such as, Ne, Kr, or Xe can be used, as in the conventional sputtering technique. In case of performing reactive sputtering involving reaction of a target material with introduced gas, there may be introduced reaction gas such as, O₂, N₂, CH₄, H₂O, or NH₃ together with the above sputtering gas to form a film of a compound of both the reaction gas and the target material. As the target material there may be used any material insofar as it can be fabricated into a cylindrical target and permits the conventional magnetron sputter discharge. The above descriptions on the sputtering gas, reactive sputtering and target material are also true of the sputtering apparatus of other embodiments which will be described later.

The sputter power source 3 used in the present invention is not limited to the one described in the above embodiment in which it is a DC power source and applies a negative voltage to both cylindrical targets 13, 13. Various known power sources for sputtering are employable. For example, the sputter power source in question may be a pulse DC power source which applies a negative voltage intermittently to a target constituting a cathode, or a so-called bipolar pulse DC power source which intermittently applies a negative voltage and applies a positive voltage of a small absolute value between the negative voltage, or an AC power source of a high or intermediate frequency including a sinusoidal wave or a pulse wave as waveform. All of these power sources can generate Penning discharge when a pair of cylindrical targets becomes negative in potential at a time.

In the above embodiment the pair of cylindrical targets 13 connected to the negative electrode of the sputter power source 3 constitutes a cathode member, while the vacuum chamber 1 connected to the positive electrode of the sputter power source 3 constitutes an anode member, but the positive electrode of the sputter power source 3 may be connected to a dedicated anode member separated from the vacuum chamber 1. These descriptions on the sputter power source and the connection thereof are also true of the sputtering apparatus of other embodiments to be described below unless a power source to be used is specified.

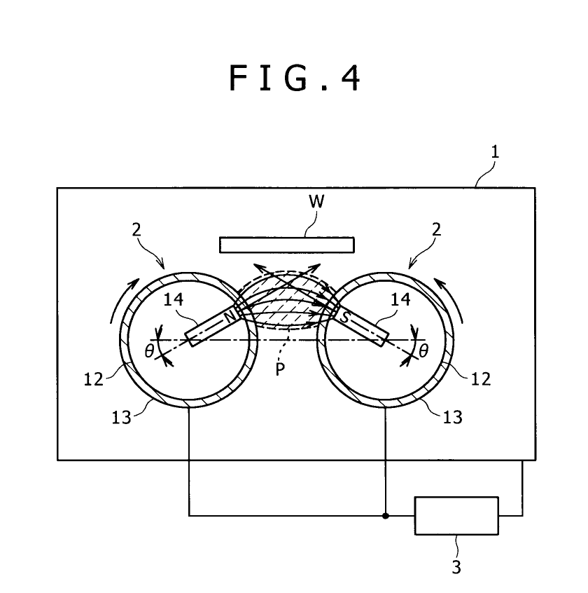

A sputtering apparatus according to a second embodiment of the present invention will be described below with reference to FIG. 4. This second embodiment is different from the previous first embodiment in that between cylindrical targets there is formed a magnetic field in which magnetic lines of force swell on the substrate side. Therefore, this point will be mainly described below. Members common to those used in the sputtering apparatus of the first embodiment are identified by common reference numerals and explanations thereof will be omitted.

Each sputter evaporation source 2 used in this second embodiment also has a cylindrical member 12, a cylindrical target 13 and a magnetic field generating member 14. However, the magnetic field generating member 14 disposed inside each cylindrical target 13 is inclined at an angle of θ toward a set position of a substrate W with respect to a reference line connecting center axes of both cylindrical targets 13, 13 and a magnetic pole center line of each magnetic field generating member 14 on a plane perpendicular to the center axes of the cylindrical targets 13.

The inclination angle θ is set preferably in the range of 0°<θ<60°, more preferably 10°≦θ≦45°. In FIG. 4 the inclination angle θ of one magnetic field generating member 14 and that of the other magnetic field generating member are equal to each other, but both inclination angles may be different from each other, insofar as the inclination angle θ of at least one magnetic field generating member 14 lies within the above range. For example, the inclination angle θ of the other magnetic field generating member 14 may be 0°. In the previous first embodiment both magnetic field generating members 14, 14 are 0° in the inclination angle θ.

The magnetic field generating members 14, 14 each having the inclination angle θ can form a magnetic field in which magnetic lines of force connecting an inner surface-side magnetic pole of one magnetic field generating member 14 and that of the other magnetic field generating member 14 swell toward the substrate W. In this way, between the cylindrical targets 13 and 13 and in the magnetic field area distorted toward the substrate W side there is formed plasma P by the foregoing Penning discharge. Consequently, the consumed position of each cylindrical target 13 is also distorted toward the substrate W side and the scattering of deposition vapor in the normal line direction from that position becomes predominant, so that the deposition particles are released further toward the substrate W side. As a result, the deposition rate for the substrate W is increased.

Each magnetic field generating member 14 referred to above may not always be fixed at its position shown in FIG. 4. It may be installed movably (i.e., rotatably) about the center axis of the associated cylindrical target 13 so as to cause a change in the inclination angle θ and may be fixed at an arbitrary position. This permits adjustment of the deposition rate under control of the magnetic field and hence the form of plasma.

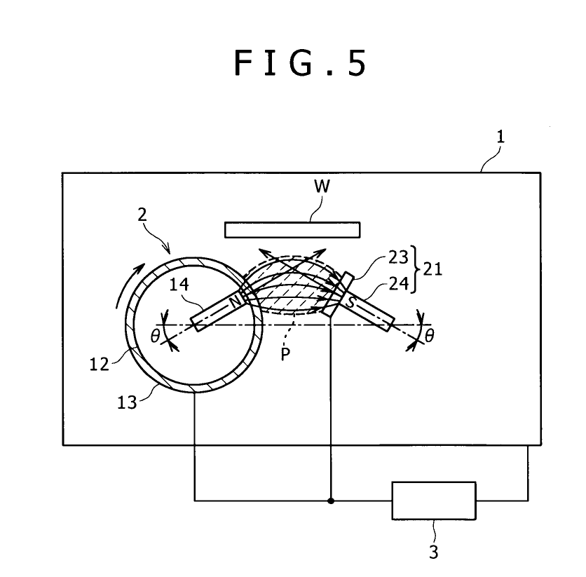

A sputtering apparatus according to a third embodiment of the present invention will now be described with reference to FIG. 5. In the above first and second embodiments the two electrode members which constitute cathodes are each constituted by the cylindrical target 13 in the associated sputter evaporation source 2, but in this third embodiment one of the sputter evaporation sources 2 is omitted and instead an auxiliary electrode structure 21 is installed within the vacuum chamber 1, constituting a single cathode. Therefore, this point will mainly be described below. Members common to those used in the sputtering apparatus of the first and second embodiment are identified by common reference numerals and explanations thereof will be omitted.

The auxiliary electrode structure 21 is provided with an auxiliary electrode member 23 and an auxiliary magnetic field generating member 24. The auxiliary magnetic field generating member 24 is the same shape as that of the magnetic field generating member 14 in each sputter evaporation source 2. That is, the auxiliary magnetic field generating member 24 is constituted by a rod-like magnet of a square cross section and is installed so as to be parallel to the center axis of both cylindrical member 12 and cylindrical target 13 in the mating sputter evaporation source 2. The auxiliary magnetic field generating member 24 is disposed in such a manner that both a magnetic pole center line of the magnetic field generating member 14 in the sputter evaporation source 2 and a magnetic pole center line of the auxiliary magnetic field generating member 24 have an inclination angle θ with respect to a reference line passing the center axis of the cylindrical target 13 and parallel to the substrate W in a cross section of the cylindrical target 13.

As to the inclination angle θ of the magnetic field generating member 14 and that of the auxiliary magnetic field generating member 24, it is preferable as in the second embodiment that at least one of the two be set at a value in the range of 0°<θ<60°, more preferably 10°≦θ≦45°. As in the first embodiment, θ may be 0°.

The auxiliary magnetic field generating member 24 has a magnetic pole (hereinafter referred to as “opposed magnetic pole”) opposed to an inner surface-side magnetic pole (that is, as described previously, a magnetic pole located near the outer periphery surface of the cylindrical member 12, namely, near the inner periphery surface of the cylindrical target 13, in the mating sputter evaporation source 2) of the magnetic field generating member 14 in the above sputter evaporation source 2, the opposed magnetic pole having a polarity opposite to the polarity of the inner surface-side magnetic pole.

The auxiliary electrode member 23 has a square band-like cross section and is disposed to be opposed to the cylindrical target 13 and on a front side of the opposed electrode of the auxiliary magnetic field generating member 24.

In the sputtering apparatus of this third embodiment, as in the second embodiment, the magnetic field generating member 14 disposed inside the cylindrical target 13 and the auxiliary magnetic field generating member 24 disposed on a back side of the auxiliary electrode member 23 form a magnetic field in the space portion between the auxiliary electrode member 23 and the cylindrical target 13, the magnetic field having magnetic lines of force swelling on the substrate W side. Therefore, when sputtering gas, e.g., Ar, is supplied into the vacuum chamber 1 and DC voltage of a negative polarity is applied to both cylindrical target 13 and auxiliary electrode member 23, there occurs Penning discharge in the area of the aforesaid magnetic field. With plasma P produced in the discharge area, the surface of the cylindrical target 13 is consumed and this consumed area is rendered uniform by rotation of the cylindrical target 13.

The voltage applied to the auxiliary electrode member 23 may be at the same level as the voltage applied to the cylindrical target 13, but in this case the auxiliary electrode member 23 is also sputtered to the same degree as the target 13. On the other hand, if an absolute value of the voltage applied to the auxiliary electrode member 23 is set lower than that of the voltage applied to the cylindrical target 13, it becomes possible to suppress the amount of sputter of the auxiliary electrode member 23. The auxiliary electrode member 23 may be floated electrically.

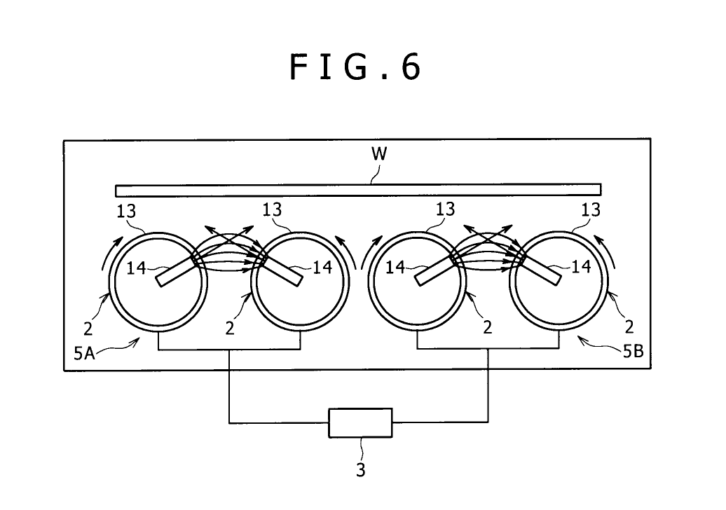

A sputtering apparatus according to a fourth embodiment of the present invention will be described below with reference to FIG. 6.

The sputtering apparatus of this fourth embodiment is provided with a first evaporation source unit 5A and a second evaporation source unit 5B. Each evaporation source unit 5A (5B) is constituted by the pair of sputter evaporation sources 2, 2 described above in the second embodiment. All the cylindrical targets 13 included in both evaporation source units 5A and 5B are disposed so as to be juxtaposed like one and same straight line. A substrate W having a large deposition area is set so as to confront the cylindrical targets 13 in a direction orthogonal to both the disposed direction and axial direction of the cylindrical targets 13.

As the sputter power source 3 there is used an AC power source having a first electrode and a second electrode. The first electrode is connected to both cylindrical targets 13, 13 included in the first evaporation source unit 5A and the second electrode is connected to both cylindrical targets 13, 13 included in the second evaporation source unit 5B.

The pair of sputter evaporation sources 2, which constitutes the evaporation source units 5A and 5B respectively, is not limited to the sputter evaporation sources 2 described in the above second embodiment. For example, they may be the sputter evaporation sources 2, 2 described in the above first embodiment. Or, the evaporation source units 5A and 5B may each be constituted by the combination of the sputter evaporation source 2 and the auxiliary electrode structure 21 described in the third embodiment.

In the sputtering apparatus of this fourth embodiment, like the so-called dual magnetron sputtering apparatus, two sets of electrodes become positive and negative in an alternate way, so that the influence of for example poisoning caused by target oxidation can be suppressed. For example, in case of forming a film having a high insulating property such as SiO2 from an Si target, the so-called disappearing anode does not occur and it is possible to effect discharge stably over a long time. Moreover, a film can be deposited efficiently also for a large-sized substrate W having a large deposition area.

In the above first to fourth embodiments, one flat plate-like substrate W is set so as to confront the space portion between the pair of sputter evaporation sources 2 and 2 or the space portion between one sputter evaporation source 2 and the auxiliary electrode structure 21. In the first embodiment, however, substrates W may be set on both sides of the aforesaid space portion respectively, as indicated with a dash-double dot line in FIG. 1. The substrate W need not always be fixed at the position opposed to the aforesaid space portion, but may be set so as to be movable to the front and rear of the space portion. This movement permits improvement of film uniformity and also permits deposition for a long substrate. This movement of the substrate W can be effected for example by the substrate W holder being installed in the vacuum chamber 1 movably.

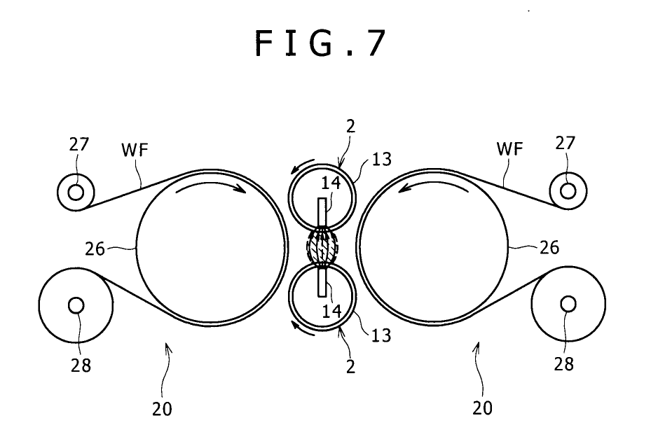

A fifth embodiment of the present invention is shown in FIG. 7. In the apparatus of this embodiment, deposition is performed for a filmy substrate WF, e.g., film or sheet, with use of the pair of sputter evaporation sources 2 described in the above first embodiment.

In this apparatus, a pair of substrate conveying mechanisms 20, 20 for conveying the filmy substrate WF is installed on both sides of the pair of sputter evaporation sources 2. Each substrate conveying mechanism 20 is provided with an unwinding roll 27 for unwinding the filmy substrate WF, a deposition roll 26 for supporting an intermediate portion of the filmy substrate WF at the deposition position, and a take-up roll 28 for taking up the filmy substrate WF.

Both deposition rolls 26, 26 are disposed on both sides of the space portion between the cylindrical targets 13 and 13 of the pair of sputter evaporation sources 2, 2 so as to confront each other in the direction orthogonal to the center axes of the cylindrical targets 13, 13. An intermediate portion of the filmy substrate WF is wound on a portion of an outer periphery surface of each deposition roll 26 which portion faces the space portion side. Each unwinding roll 27 unwinds new portion of the filmy substrate WF in response to the rotation of each deposition roll 26. Each take-up roll 28 takes up the filmy substrate WF after deposition in accordance with rotation of the associated deposition roll 26.

In this apparatus, while each deposition roll 26 rotates to feed the substrate WF on the deposition roll 26 downstream in a successive manner, a film is deposited by sputtering on the substrate WF (i.e., the portion opposed to the space portion) that is positioned on the deposition roll 26. In this apparatus, one of the substrate conveying mechanisms 20, 20 may be omitted.

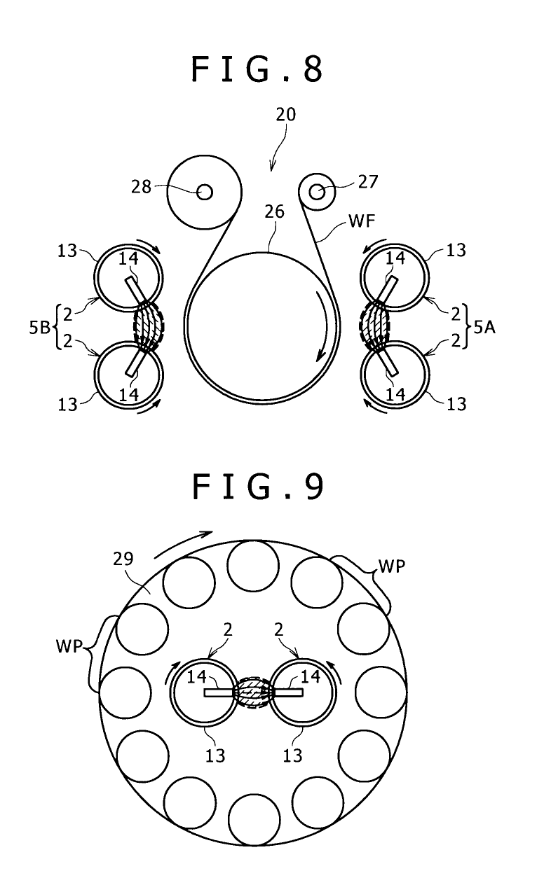

A sputtering apparatus according to a sixth embodiment of the present invention is shown in FIG. 8. This apparatus is provided with a first evaporation source unit 5A, a second evaporation source unit 5B, and a substrate conveying mechanism 20 for conveying a filmy substrate WF between the units 5A and 5B. Like the substrate conveying mechanisms 20 described in the above fifth embodiment, the substrate conveying mechanism 20 is provided with a deposition roll 26, an unwinding roll 27, and a take-up roll 28, with the filmy substrate WF being wound on an outer periphery surface of the deposition roll 26.

The first evaporation source unit 5A is disposed at a position where a film is to be deposited on the filmy substrate WF wound on an upstream-side portion in the rotational direction of the outer periphery surface of the deposition roll 26. Likewise, the second evaporation source unit 5B is disposed at a position where a film is to be deposited on the filmy substrate WF wound on a downstream-side portion in the rotational direction of the outer periphery surface of the deposition roll 26. Each of the evaporation source units 5A and 5B is provided with the pair of sputter evaporation sources 2, 2 described in the second embodiment and shown in FIG. 4. The evaporation source units 5A and 5B are disposed in such a manner that magnetic lines of force in the magnetic field formed between the sputter evaporation sources 2 swell toward the filmy substrate WF wound on the deposition roll 26.

Also in this sixth embodiment both evaporation source units 5A and 5B can deposit a film on the filmy substrate WF while the deposition roll 26 rotates to convey the filmy substrate WF.

In this embodiment the material of the cylindrical targets 13 in the evaporation source unit 5A and that of the cylindrical targets 13 in the evaporation source unit 5B may be the same or different. One of the evaporation source units 5A and 5B may be omitted. The apparatus provided with the first evaporation source unit 5A and the second evaporation source unit 5B as illustrated in the drawing can be a modification of the sputtering apparatus of the above fourth embodiment. For example, the modification may be such that an AC power source having a first electrode and a second electrode is used as the sputter power source, the cylindrical targets 13, 13 in the first evaporation source unit 5A are connected to the first electrode, and the cylindrical targets 13, 13 in the second evaporation source unit 5B are connected to the second electrode.

A sputtering apparatus according to a seventh embodiment of the present invention is shown in FIG. 9. This apparatus is adapted to deposition for a cylindrical substrate WP and is provided with the pair of sputter evaporation sources 2, 2 described in the above first embodiment and a rotary table 29. The rotary table 29 has a circular plane shape. Both sputter evaporation sources 2, 2 are disposed above a rotational center position of the rotary table 29. The rotary table 29 holds cylindrical substrates WP in a stand-up on an outer periphery portion thereof and at a plurality of circumferential positions thereof. The rotary table 29 causes the cylindrical substrates WP to revolve around the sputter evaporation sources 2, 2 so as to displace themselves relatively with respect to the sputter evaporation sources 2, 2 while causing the cylindrical substrates WP to rotate about the respective center axes.

In this apparatus, deposition particles released from both sides of a space portion between the cylindrical targets 13 and 13 included in the sputter evaporation sources 2, 2, respectively, are deposited on outer periphery surfaces of the cylindrical substrates WP which are rotating about their own axes while revolving on the rotary table 29, thereby forming films. Thus, deposition for the outer periphery surfaces of the plural cylindrical substrates WP is done efficiently at a time.

This apparatus is applicable also to deposition for other substrates than the cylindrical substrates WP. For example, there may be adopted a configuration wherein a cylindrical substrate holder is provided instead of the cylindrical substrates WP on the rotary table 29 and substrates of various shapes are held by the substrate holder. Further, the evaporation source units disposed at the rotational center position of the rotary table 29 may be those described in the second or the third embodiment.

Thus, the present invention provides a sputtering apparatus able to suppress local consumption at axial ends of a rotatable cylindrical target, thereby making an erosion area on the cylindrical target uniform to improve the service life of the target.

More specifically, the first sputtering apparatus according to the present invention comprises a pair of sputter evaporation sources and a sputter power source for the supply of discharge electric power to the sputter evaporation sources. Each of the sputter evaporation sources has a cylindrical target, the cylindrical target having a center axis and being disposed rotatably about the center axis, and a magnetic field generating member disposed in a direction parallel to the center axis of the cylindrical target. The cylindrical targets in the sputter evaporation sources are disposed in such a manner that the respective center axes are parallel to each other, and with the cylindrical targets as cathodes, the sputter power source supplies discharge electric power to the cylindrical targets. The magnetic field generating members in both sputter evaporation sources generate a magnetic field having magnetic lines of force which act in directions attracting through the surfaces of the cylindrical targets in the sputter evaporation sources.

The magnetic field thus formed between the cylindrical targets which constitute cathodes traps electrons generated by ionization of sputtering gas during deposition, causing Penning discharge to take place in the area of the magnetic field. The Penning discharge occurs strongly in the magnetic field-existing area, while at an outer periphery portion thereof there occurs plasma drift caused by an electric field, so that substantially uniform discharge plasma occurs in the discharge-existing area. Thus, unlike magnetron discharge which occurs in conventional sputtering apparatus, there exist no arcuate plasma portions connecting end portions of two linear plasmas, so that at the time of deposition by rotation of the cylindrical targets, deposition particles can evaporate quickly and uniformly from the outer periphery surfaces of the cylindrical targets corresponding to the plasma area. This prevents local consumption of the cylindrical targets and thereby improves the utilization rate and hence the service life of the cylindrical targets.

Further, this sputtering apparatus has the following advantages in point of deposition. Since the substrate is installed at a position deviated from the discharge area, there is no fear of strong radiation of plasma to the film during deposition. Therefore, it is possible to avoid ion bombardment or the like. Moreover, strong radiation of ions reflected by the targets' surfaces or negative ions produced at the targets' surfaces to the substrate is suppressed. Further, in the conventional rotary magnetron sputter evaporation source the surface of a target undergoes a significant change in the intensity of a magnetic field with consumption of the target, whereas in the sputtering apparatus according to the present invention the change in the intensity of a magnetic field with consumption of each target is less conspicuous, thus permitting the use of for example a cylindrical target of a large wall thickness. This prolongs the depositable time using a single target and improves productivity.

In the sputtering apparatus described above, the magnetic field generating member in at least one sputter evaporation source may be provided so as to form magnetic lines of force swelling toward the substrate side. Further, the magnetic field generating member in the at least one sputter evaporation source may be provided so as to permit such a movement as changes the swelling of the magnetic lines of force.

The magnetic field having magnetic lines of force which swell toward the substrate side as noted above makes it possible to shift the plasma generating area from between cylindrical targets to the substrate side. The plasma produced in this area can cause sputter vapor evaporated from the cylindrical targets' surfaces to be released further toward one direction, thus making it possible to increase the deposition rate for the substrate W disposed in that vapor releasing direction. Further, if the magnetic field generating members are provided movably so as to make the swelling of the magnetic lines of force changeable, the deposition rate for the substrate can be adjusted by controlling the plasma generating area.

As the sputter power source used in the above sputtering apparatus there may be used a DC power source, an intermittent DC power source which includes a voltage zero or opposite polarity period repeatedly, or an AC power source. All of these types of power sources can produce Penning discharge when both a pair of cylindrical targets becomes negative in potential.

The above sputtering apparatus may comprise a first evaporation source unit constituted by a pair of sputter evaporation sources each having the above cylindrical target and the above magnetic field generating member and a second evaporation source unit constituted by another pair of sputter evaporation sources each having the above cylindrical target and the above magnetic field generating member, wherein the sputter power source is an AC power source having a first output end and a second output end, the first output end being connected to the pair of cylindrical targets in the first evaporation source unit, wherein the power sputter source is an AC power source having a first output end and a second output end, the first output end being connected to the pair of cylindrical targets in the first evaporation source unit and the second output end being connected to the pair of cylindrical targets in the second evaporation source unit. Thus, like the so-called dual magnetron sputtering apparatus, the apparatus having both first and second evaporation source units can suppress disappearing anode phenomenon in case of depositing a insulating film such as an oxide film.

The second sputtering apparatus according to the present invention comprises a sputter evaporation source, a sputter power source, and an auxiliary electrode structure. The sputter evaporation source has a cylindrical target, the cylindrical target having a center axis and being disposed rotatably about the center axis, and a magnetic field generating member disposed in a direction parallel to the center axis of the cylindrical target, wherein the sputter power source supplies discharge electric power to the cylindrical target with the cylindrical target as a cathode. The auxiliary electrode structure has an auxiliary electrode member disposed opposingly in parallel with or approximately in parallel with the cylindrical target in the sputter evaporation source and an external auxiliary magnetic field generating member attached to the auxiliary electrode member. The auxiliary magnetic field generating member and the magnetic field generating member provided in the sputter evaporation source generate a magnetic field having magnetic lines of force acting in directions attracting through the surface of the cylindrical target.

Also in this second sputtering apparatus at least one of the magnetic field generating member in the sputter evaporation source and the auxiliary magnetic field generating member may be provided so as to swell the magnetic lines of force toward the substrate side. Further, the member in question may be provided movably so as to change the swelling of the magnetic lines of force.

Since this second sputtering apparatus has the auxiliary electrode structure, it is possible to expect the same effect as in the first sputtering apparatus also in case of using a single sputter evaporation source. The auxiliary electrode member may be connected as a cathode to a sputter electrode together with the cylindrical target in the sputter evaporation source, or may be floated electrically.

1. A sputtering apparatus for depositing deposition particles on a surface of a substrate to form a film, the deposition particles having been sputter-evaporated from a surface of a target within sputtering gas introduced into a vacuum chamber, the sputtering apparatus comprising:
a pair of sputter evaporation sources each having a cylindrical target and a magnetic field generating member, said cylindrical target having a center axis and being disposed so as to be rotatable about the center axis, said magnetic field generating member being disposed inside said cylindrical target and being disposed in a direction parallel to the center axis of said cylindrical target; and
a sputter power source for the supply of discharge electric power to said cylindrical targets in said sputter evaporation sources, using said cylindrical targets as cathodes,
wherein said cylindrical targets in said sputter evaporation sources are disposed so as to confront each other in parallel or approximately in parallel with each other, and said magnetic field generating members generate a magnetic field having magnetic lines of force acting in directions attracting through surfaces of said pair of cylindrical targets.

2. The sputtering apparatus according to claim 1, wherein said magnetic field generating member in each of said sputter evaporation source is disposed in such a manner that the magnetic lines of force swell toward the substrate side.

3. The sputtering apparatus according to claim 1, wherein said magnetic field generating member in at least one of said pair of sputter evaporation sources is disposed so as to permit such a movement thereof as changes the swelling of the magnetic lines of force.

4. The sputtering apparatus according to claim 1, wherein said sputter power source is any of a DC power source, an intermittent DC power source including a voltage zero or opposite polarity period repeatedly, and an AC power source.

5. The sputtering apparatus according to claim 1, comprising:
a first evaporation source unit constituted by a pair of sputter evaporation sources each having said cylindrical target and said magnetic field generating member; and
a second evaporation source unit constituted by another pair of sputter evaporation sources each having said cylindrical target and said magnetic field generating member,
wherein said sputter power source is an AC power source having a first output end and a second output end, said first output end being connected to said pair of cylindrical targets in said first evaporation source unit and said second output end being connected to said pair of cylindrical targets in said second evaporation source unit.

6. A sputtering apparatus for depositing deposition particles on a surface of a substrate to form a film, the deposition particles having been sputter-evaporated from a surface of a target within sputtering gas introduced into a vacuum chamber, the sputtering apparatus comprising:
a sputter evaporation source, said sputter evaporation source having a cylindrical target, said cylindrical target having a center axis and being disposed rotatably about the center axis, and a magnetic field generating member disposed inside said cylindrical target and in a direction parallel to the center axis of said cylindrical target;
an auxiliary electrode structure, said auxiliary electrode structure having an auxiliary electrode member disposed opposingly in parallel or approximately in parallel with said cylindrical target in said sputter evaporation source and an auxiliary magnetic field generating member attached to said auxiliary electrode member; and
a sputter power source for the supply of discharge electric power to at least said cylindrical target in said sputter evaporation source with said cylindrical target as a cathode,
wherein said magnetic field generating member provided in said sputter evaporation source and said auxiliary magnetic field generating member generate a magnetic field having magnetic lines of force acting in directions attracting through a surface of said cylindrical target.

7. Said magnetic field generating member in said sputter evaporation source and said auxiliary magnetic field generating member are provided in such a manner that the magnetic lines of force swell toward the substrate side.
